(19) United States
(12) Patent Application Publication
(10) Pub. No.: US 2026/0068777 A1
(43) Pub. Date: Mar. 5, 2026

(54) ELECTRONIC DEVICE WITH INDENTED DIE BACKSIDE

(71) Applicant: Texas Instruments Incorporated, Dallas, TX (US)

(72) Inventors: Yutaka Suzuki, Allen, TX (US); Guangxu Li, Allen, TX (US); Blake Travis, Richardson, TX (US); Thomas Kronenberg, Dallas, TX (US); Jaimal Williamson, McKinney, TX (US); Rajen Manicon Murugan, Dallas, TX (US); Sylvester Ankamah-Kusi, McKinney, TX (US)

(21) Appl. No.: 18/822,124

(22) Filed: Aug. 31, 2024

(51) Int. Cl. H01L 23/498; H01L 23/10; H01L 23/373

(52) U.S. Cl. CPC H01L 23/49816

(57) ABSTRACT

An electronic device includes a substrate having conductive features, and a semiconductor die having conductive terminals along a first side, and an indent that extends into an opposite second side, the conductive terminals attached to respective ones of the conductive features of the substrate. A method of fabricating an electronic device includes forming an indent into a second side of a semiconductor die and attaching conductive terminals along an opposite first side of the semiconductor die to respective conductive features of a substrate.

### BACKGROUND

Flip chip electronic devices can be susceptible to board level reliability (BLR) challenges caused by materials with different coefficients of thermal expansion (CTE). Temperature cycling (TC) can identify BLR issues such as external solder joint cracking, as well as inter level dielectric (ILD) or other back-end-of-line (BEOL) film cracking, or copper trace cracking in a substrate under the die. A CTE mismatch between a silicon die and an underfill material can induce potential underfill delamination and contribute to the BEOL damage. Different molding compound materials can be used to mitigate CTE mismatching but this can increase cost and cause other difficulties during manufacturing.

### SUMMARY

In one aspect, an electronic device includes a substrate and a semiconductor die having opposite first and second sides, conductive terminals along the first side, and an indent that extends into the second side, the conductive terminals coupled to respective conductive features of the substrate.

In another aspect, a system includes a circuit board having a conductive feature and an electronic device that includes a substrate having first conductive features, and a second conductive feature that is soldered to conductive feature of the circuit board. The electronic device includes a semiconductor die having opposite first and second sides, conductive terminals along the first side, and an indent extending into the second side, where the conductive terminals are coupled to respective ones of the first conductive features of the substrate.

In a further aspect, a method of fabricating an electronic device includes forming an indent into a second side of a semiconductor die and attaching conductive terminals along an opposite first side of the semiconductor die to respective conductive features of a substrate.

### BRIEF DESCRIPTION OF THE DRAWINGS

FIG. 1 is a partial sectional side elevation view of a flip chip quad flat no-lead (FCQFN) electronic device on a system circuit board taken along line 1-1 of FIG. 1A having a flip chip semiconductor die attached to a substrate with a backside indent along four lateral sides.

FIG. 1A is a top plan view of the electronic device of FIG. 1.

FIG. 1B is a bottom view of the electronic device of FIGS. 1 and 1A.

FIG. 1C is a graph of plastic work density for different lead positions of the electronic device of FIGS. 1-1B.

FIG. 2 is a sectional side elevation view of another FCQFN electronic device taken along line 2-2 of FIG. 2A having a flip chip semiconductor die attached to a substrate with backside indents at four lateral corners.

FIG. 2A is a top plan view of the electronic device of FIG. 2.

FIG. 2B is a sectional side elevation view of the electronic device taken along line 2B-2B of FIG. 2A.

FIG. 3 is a sectional side elevation view of another FCQFN electronic device taken along line 3-3 of FIG. 3A having a flip chip semiconductor die attached to a substrate with a backside indent that extends along three lateral sides and a portion of a fourth lateral side.

FIG. 3A is a top plan view of the electronic device of FIG. 3.

FIG. 3B is a sectional side elevation view of the electronic device taken along line 3B-3B of FIG. 3A.

FIG. 4 is a sectional side elevation view of a flip chip ball grid array (FCBGA) electronic device taken along line 4-4 of FIG. 4A having a flip chip semiconductor die attached to a substrate with a backside indent along four lateral sides.

FIG. 4A is a top plan view of the electronic device of FIG. 4.

FIG. 5 is a sectional side elevation view of another FCBGA electronic device taken along line 5-5 of FIG. 5B having a flip chip semiconductor die attached to a substrate with a backside metal lid with a backside indent along four lateral sides and thermal interface material extending into the indent.

FIG. 5A is a sectional side elevation view of an alternate implementation of the FCBGA electronic device of FIG. 5 having a flip chip semiconductor die attached to a substrate with a backside metal lid with a backside indent along four lateral sides and thermal interface material that does not extend into the indent.

FIG. 5B is a top plan view of the electronic device of FIG. 5.

FIG. 6 is a flow diagram of a method of fabricating an electronic device.

FIGS. 7-13 show the example FCQFN electronic device of FIGS. 1-1B undergoing fabrication processing according to an implementation of the method of FIG. 6.

FIGS. 14-16 show an example of the FCBGA electronic device of FIGS. 4 and 4A undergoing fabrication processing according to another implementation of the method of FIG. 6.

FIGS. 17-20 show an example of the FCBGA electronic device of FIGS. 5-5B undergoing fabrication processing according to another implementation of the method of FIG. 6.

FIG. 21 is a sectional side elevation view of another FCBGA electronic device having a flip chip semiconductor die attached to a substrate with a backside indent and a second semiconductor die attached to a substrate with a backside indent with bond wire connections to the substrate.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various structures and methods of the present disclosure may be beneficially applied to an electronic apparatus such as an integrated circuit and manufacturing electronic devices. While such examples may be expected to provide various improvements, no particular result is a requirement of the present disclosure unless explicitly recited in a particular claim.

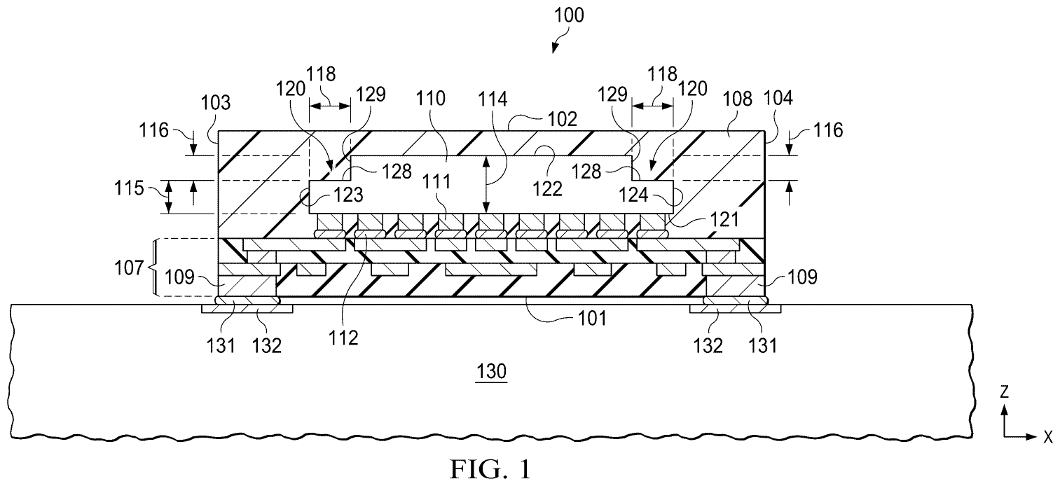

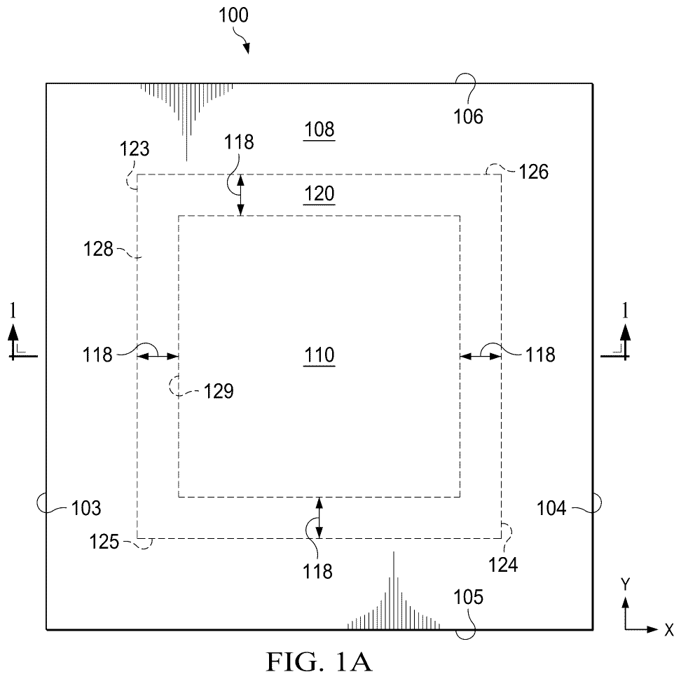

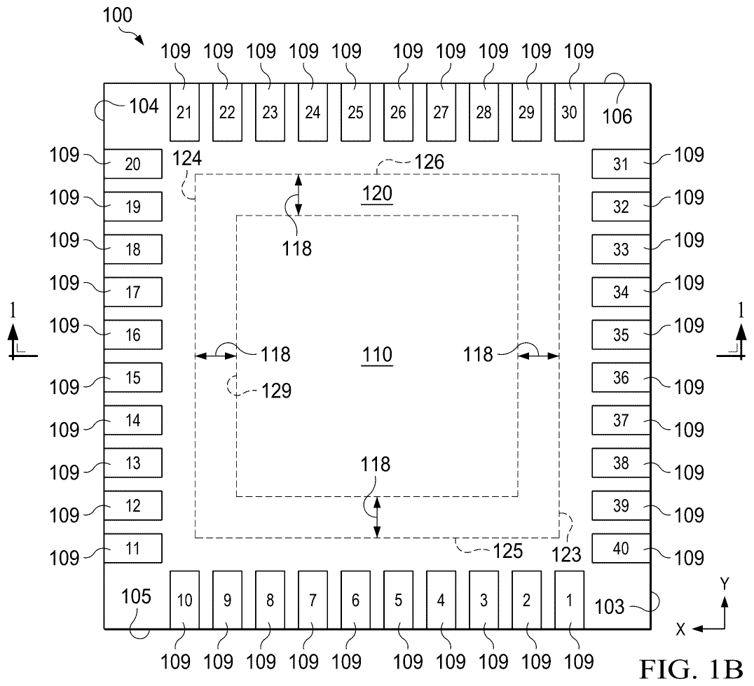

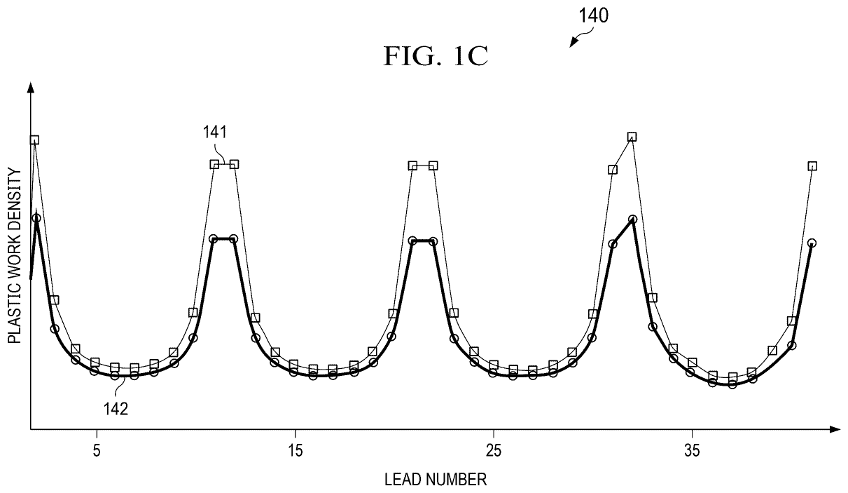

FIGS. 1-1B show an example flip chip quad flat no-lead (FCQFN) electronic device 100 with an indent 120 in a die backside to control CTE mismatch effects and help enhance board level reliability. FIG. 1 shows a sectional side view taken along line 1-1 of FIG. 1A, FIG. 1A shows a top view, and FIG. 1B shows a bottom view of the electronic device 100. The electronic device 100 and other example electronic devices are illustrated herein in an example position in a three-dimensional space with respective first, second, and third mutually orthogonal directions X, Y (FIGS. 1A and 1B), and Z (FIG. 1). The electronic device 100 includes opposite first and second (e.g., bottom and top) sides 101 and 102 (FIG. 1) that are spaced apart from one another along the third direction Z. The electronic device 100 also includes third and fourth sides 103 and 104 that are spaced apart from one another along the first direction X, and fifth and sixth sides 105 and 106 (FIGS. 1A and 1B) that are spaced apart from one another along the second direction Y. The electronic device 100 includes a substrate 107 (FIG. 1) along the first side 101 and a package structure 108 (e.g., a molded plastic structure as shown in FIGS. 1 and 1A) that extends from the top side of the substrate 107 to the second side 102. The substrate 107 in one example is a multilevel package substrate or a routable lead frame structure with conductive routing traces, conductive vias, and conductive metal leads 109 with bottom sides exposed along the first side 101 (FIGS. 1 and 1B). The substrate 107 also includes top side conductive metal features (e.g., metal pads) allowing soldering to bond wires and/or conductive metal terminals of attached electronic components such as by flip-chip soldering, surface mount component soldering, etc. The substrate trace and via routings provide desired electrical connections between the components of the device 100 and the leads 109 of the substrate 107.

The electronic device 100 has a semiconductor die 110 that is fully or at least partially enclosed by the package structure 108. In the illustrated example, the semiconductor die 110 has conductive metal terminals 111 (e.g., copper pillars or bumps in FIG. 1) that are attached and directly electrically coupled by solder 112 to respective first conductive features along the top side of the substrate 107. Other electronic components (not shown) can be included, such as further semiconductor dies, passive or active surface mount components (e.g., resistors, capacitors, inductors, transformers, diodes, transistors, etc.) or combinations thereof. The package structure 108 extends on a portion of the top side of the substrate 107 and may extend underneath the bottom side 121 of the semiconductor die 110 in the flip-chip attached implementation as shown in FIG. 1. The electronic device 100 is shown in FIG. 1 installed on a system circuit board 130 having corresponding conductive features 132 on a top side thereof, with the conductive leads 109 of the substrate 107 electrically coupled to corresponding conductive features 132 of the circuit board 130 by solder 131.

The semiconductor die 110 has opposite first and second sides 121 and 122. The first side 121 is the die front side and the second side 122 is the die back side. The conductive terminals 111 are located along the first side 121 and are coupled to respective ones of the first conductive features of the substrate 107 by flip chip soldering via solder tips 112. The conductive metal terminals 111 in one example extend outward (e.g., downward) from the first side 121 of the semiconductor die 110 along the third direction Z (FIG. 1). The semiconductor die 110 also has respective lateral third and fourth sides 123 and 124 (FIGS. 1-1B) and lateral fifth and sixth sides 125 and 126 (FIGS. 1A and 1B).

The first or bottom side 121 and the second or top side 122 are spaced apart from one another along the third direction Z by a nominal die thickness 114 (FIG. 1). In one example, the nominal die thickness 114 is approximately 200 μm. The respective lateral third and fourth sides 123 and 124 are spaced apart from one another along the first direction X, and the respective fifth and sixth sides 125 and 126 are spaced apart from one another along the second direction Y in the illustrated orientation. The sides 121 and 122 in one example extend in approximately parallel planes of the first and second directions (e.g., respective X-Y planes), although not a requirement of all possible implementations. The sidewalls 123 and 124 individually extend between the sides 121 and 122 and extend in approximately parallel planes of the second and third directions (e.g., respective Y-Z planes), although not a requirement of all possible implementations.

The semiconductor die 110 has an indent 120 that extends downward into the second side 122 (e.g., along the third direction Z). The indent 120 has a depth 116 along the third direction Z, and the indent 120 has a lateral width 118 (e.g., the lateral extent inward from the respective lateral sides 123-126). As shown in FIG. 1, the semiconductor die 110 has a thickness 115 below the indent 120. In one example, the depth 116 of the indent 120 is approximately 30% to 70% of the nominal die thickness 114, such as approximately half the nominal die thickness 114. In one implementation, the nominal die thickness 114 is approximately 200 μm and the depth 116 of the indent 120 is approximately 130 μm, and the indent width 118 is approximately 700 μm. In the illustrated example, the indent width 118 is greater than the indent depth 116. As best shown in FIG. 1, the example indent 120 has a bottom side or ledge 128 and a sidewall 129. The indent bottom side 128 and the sidewall 129 are generally flat or planar in one example, although not a requirement of all implementations. In other examples, one or both of the bottom side 128 and the sidewall 129 can be nonplanar and can have contoured shapes or profiles that can be linear, curved, or other shapes depending on the manufacturing processing used in forming the indent 120.

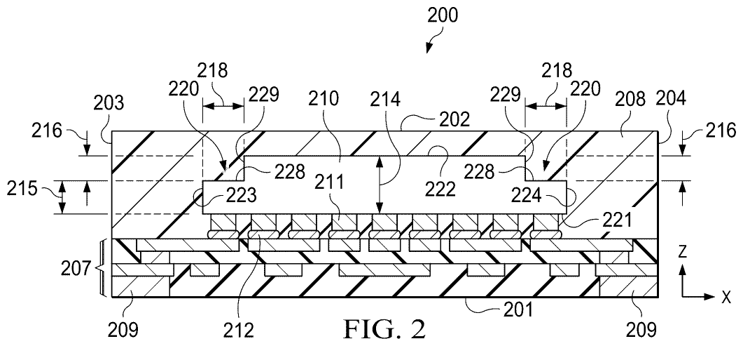

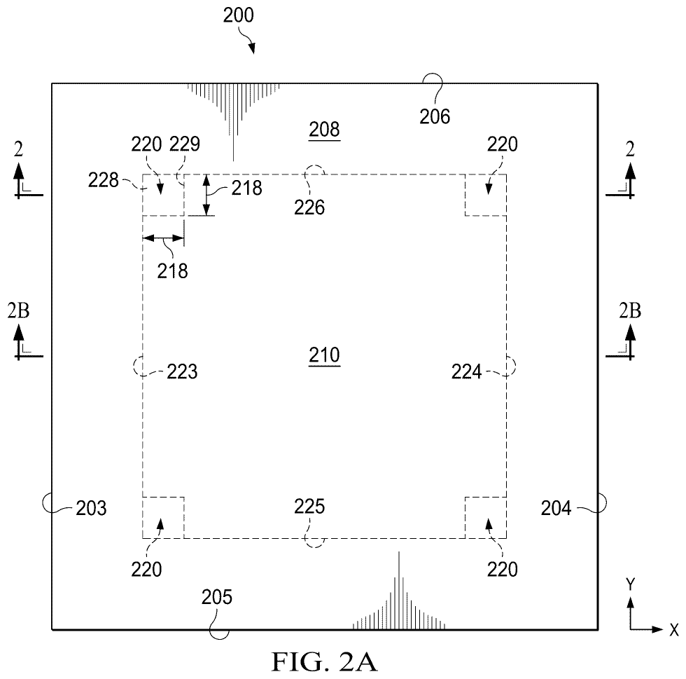

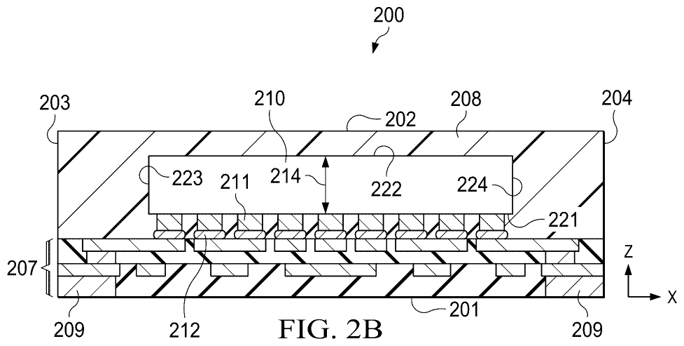

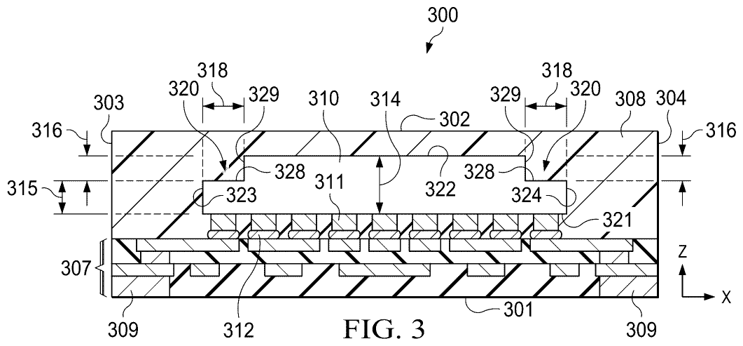

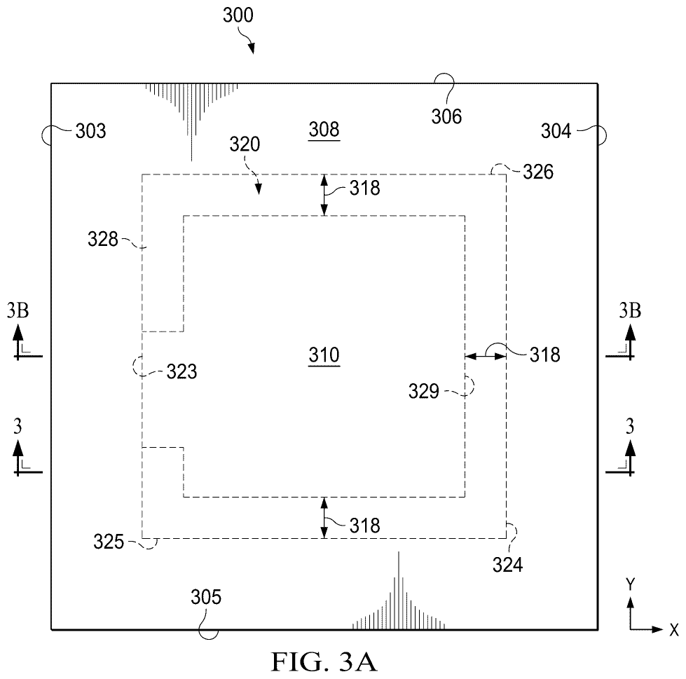

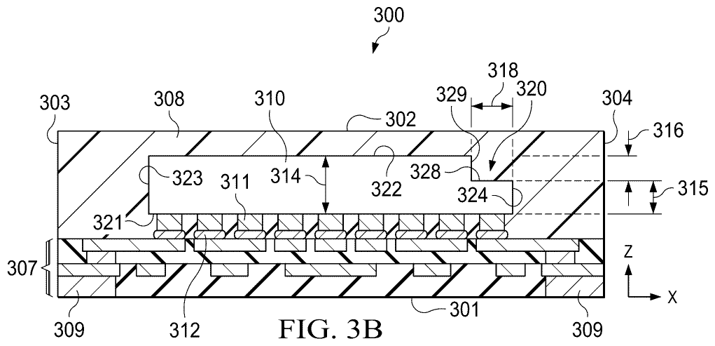

As shown in FIGS. 1A and 1B, the example indent 120 extends around the entire periphery of the semiconductor die 110 into the second side 122 and along all four lateral sides 123-126, although not a requirement of all possible implementations. In other examples, multiple indents can be used (e.g., FIGS. 2-2B below). In certain implementations, moreover, the indent 120 can extend along less than an entire lateral side of the semiconductor die 110 (e.g., FIGS. 2-3B below). In other implementations, the indent 120 or indents can extend along fewer than all lateral sides 123-126 of the semiconductor die 110. In the illustrated example, the package structure 108 extends in the indent 120 and encloses the semiconductor die 110, including along portions of the first side 221 between the conductive terminals 111, although not a requirement of all possible implementations.

Referring also to FIGS. 1B and 1C, the bottom view of FIG. 1B shows example pin or lead numbers for the leads 109 along the lateral sides 103-106 of the example QFN electronic device 100. The illustrated example has pins or leads 1-10 along the fifth side 105, the leads 11-20 along the fourth side 104, leads 21-30 along the sixth side 106, and leads 31-40 along the third side 103. In other examples, different pin configurations can be used. FIG. 1C shows a graph 140 with respective board level reliability model curves 141 and 142 illustrating plastic work density for different lead positions of the electronic device of FIGS. 1-1B with the indent 120 (curve 142) and a baseline design (curve 141) without the indent 120.

As shown in the baseline curve 141, a semiconductor die with no indent 120 has the full nominal thickness 114 which presents a thick structure along the lateral sidewalls 123-126 and particularly near the lateral corners of the semiconductor die 110 having a coefficient of thermal expansion (CTE) corresponding to the material of the semiconductor die (e.g., silicon). The molding compound of the package structure 108 abuts the lateral sides of the semiconductor die and the bottom or first side 121 of the semiconductor die. The conductive terminals 111 are attached to the top side of the substrate 107, which has a higher CTE value than the semiconductor die. In certain examples, the semiconductor die (e.g., silicon) and the back end of line ILD layer(s) of the semiconductor die have relatively low CTE values, compared with the higher CTE values of the substrate 107, the conductive terminals (e.g., copper pillars) 111 and protective coating overlying the ILD structure (e.g., polyamide) as well as the solder 112 used to flip chip attach the semiconductor die to the substrate 107.

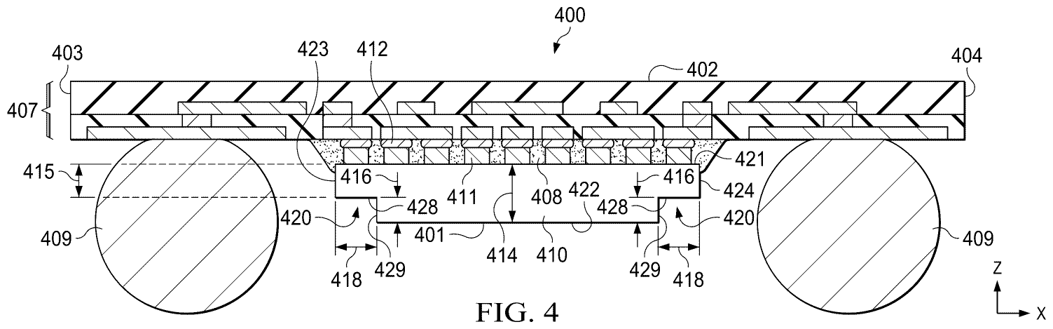

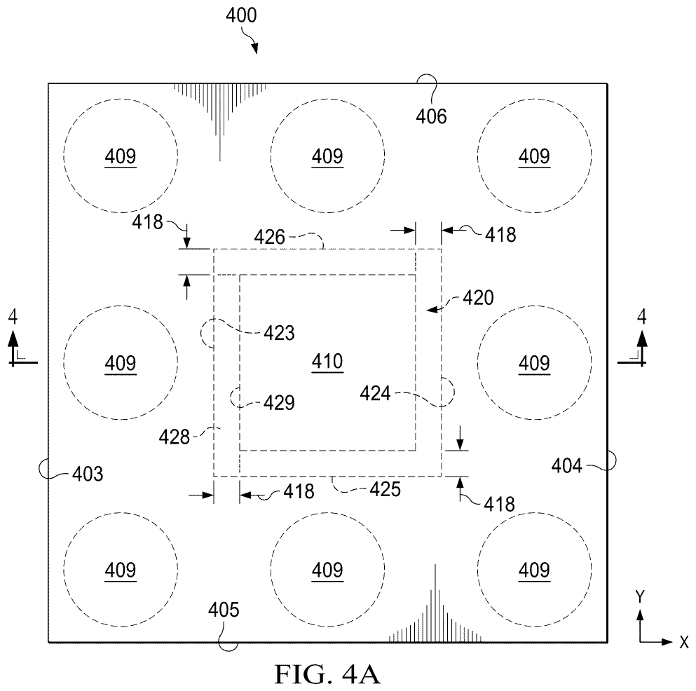

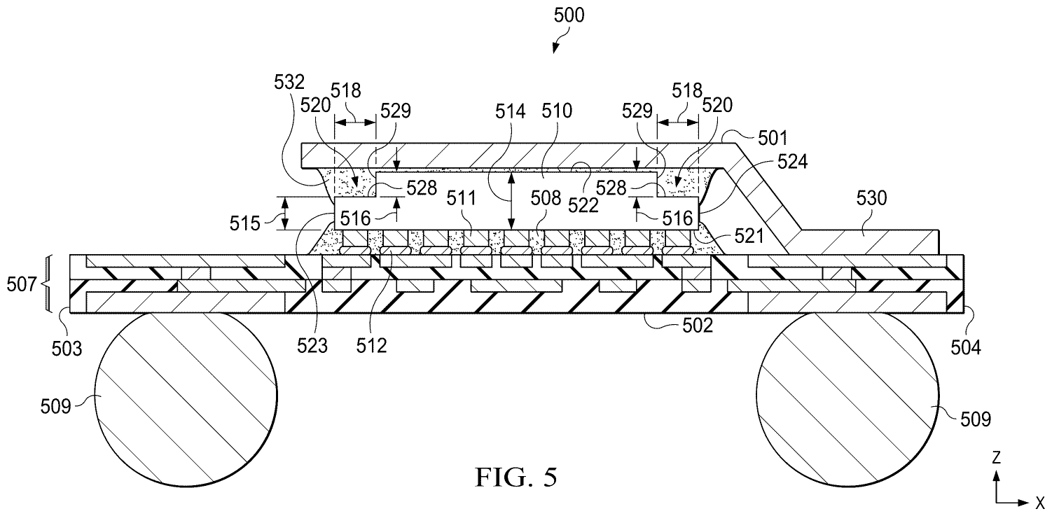

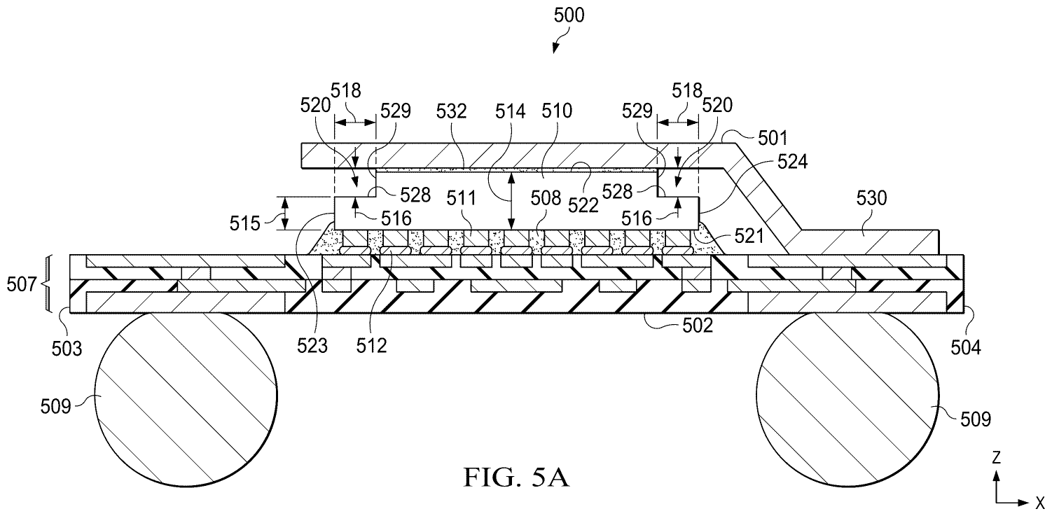

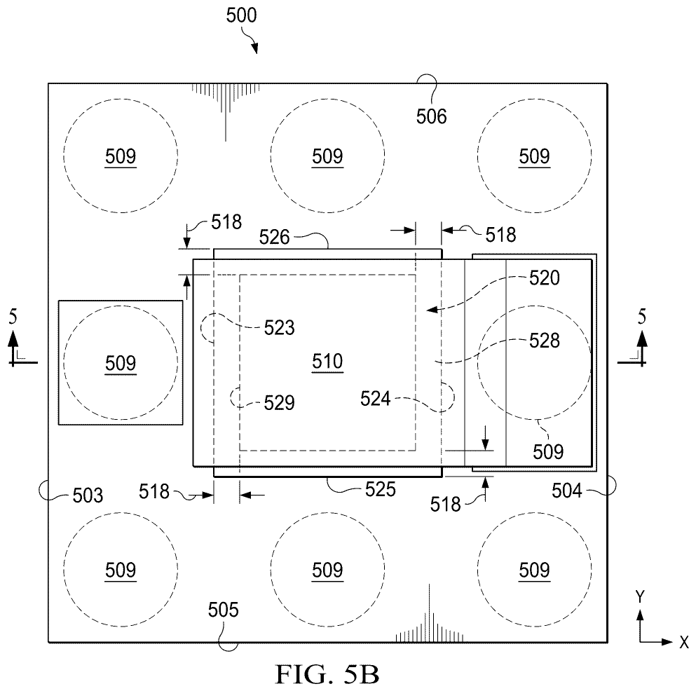

The CTE mismatching of the structural elements of the baseline device modeled by the curve 141 in FIG. 1C tends to result in high mismatch at the lateral corners of the rectangular substrate and rectangular semiconductor die, illustrated as peaks in the curve near the device leads (e.g., 1, 10, 11, 20, 21, 30, 31, and 40) that are proximate to the lateral corners. The indent 120 in this example extends around the periphery of the second side 122 of the semiconductor die 110 (e.g., the periphery of the die back side) including the lateral corners of the semiconductor die 110. The indent 120 in this example is filled in with mold compound of the package structure 108, which effectively mitigates the CTE mismatch at or near the lateral corners of the semiconductor die in the electronic device 100. The modeled curve 142 represents the plastic work density of the example electronic device 100 and shows approximately 28% reduction in the maximum plastic work density compared with the baseline curve 141. Reduced plastic work density helps to reduce the risk of solder joint cracks, and other board level reliability issues associated with CTE mismatch, and leads to enhanced (e.g., longer) board level reliability lifetime estimates in a given system installation of the electronic device 100. Other packaged electronic device types and forms also benefit from semiconductor die backside indents (e.g., ball grid array or BGA package types as shown in FIGS. 4-5B below).

The presence, size, and location of the indent 120 can impact thermal performance of the electronic device 100. In certain implementations, the indent 120 can be preferentially located at or near corners of the semiconductor die 110 as discussed above. Removal of a portion of the semiconductor die thickness can reduce local thermal performance near the indent 120. In certain implementations, the indent 120 can be terminated or reduced in size at or near semiconductor die hotspots or locations at which high thermal conductivity is beneficial to a given electronic device design (e.g., FIGS. 3-3B below). Flip chip packaged devices may benefit from increased silicon die thickness to help mitigate large temperature gradients due to hot spots on the die. However, as discussed above, increased die thickness can be detrimental to package mechanical reliability. This trade-off can be accommodated in a given design by selectively localizing the placement and sizing of the indent 120 and/or providing multiple indents, for example, at or near the lateral corners of the die back side 122, and preferentially away from hotspots or other thermally sensitive areas of the semiconductor die 110, alone or in combination with designing the semiconductor die such that heat sources and/or thermally sensitive circuits of the active area along the first or front side 121 of the semiconductor die 110 are preferentially positioned in the lateral interior of the semiconductor die 110, so that any thermal resistance increase in the areas having the indent or indents 120 is negligible in the thermally sensitive areas.

FIGS. 2-2B illustrate another example FCQFN electronic device 200. FIG. 2 shows a side section view of the electronic device 200 taken along line 2-2 of a top view in FIG. 2A, and FIG. 2B shows a side section view of the electronic device 200 taken along line 2B-2B of FIG. 2A. The electronic device 200 includes structures and features 201-216, 218, 220-226, 228, and 229 that generally correspond to the respective structures and features 101-116, 118, 120-126, 128, and 129 described above in connection with FIGS. 1-1B except as described differently hereinafter. In this example, the semiconductor die 210 includes multiple indents 220 that are located at or near the peripheral corners of the back or second side 222 of the semiconductor die 210, as best shown in FIG. 2A. The positioning of the indents 220 near the lateral corners facilitates reduced plastic work density to provide benefits similar to those illustrated and described above in connection with FIG. 1C. In addition, the indents 220 do not extend along the entire length of the lateral sides 223-226 and may provide better thermal performance particularly for high power components (e.g., transistors) and/or thermally sensitive circuitry along portions of the periphery of the semiconductor die 210 that do not include the indents 220.

FIGS. 3-3B illustrate another example FCQFN electronic device 300. FIG. 3 shows a side section view of the electronic device 300 taken along line 3-3 of a top view in FIG. 3A, and FIG. 3B shows a side section view of the electronic device 300 taken along line 3B-3B of FIG. 3A. The electronic device 300 includes structures and features 301-316, 318, 320-326, 328, and 329 that generally correspond to the respective structures and features 101-116, 118, 120-126, 128, and 129 described above in connection with FIGS. 1-1B except as described differently hereinafter. In this example, the semiconductor die 310 includes a single indent 320 that extends into the die backside along the entirety of three lateral sides 324-326 including all four of the peripheral corners as shown in FIG. 3A. The indent 320 in this example extends along only a portion of the third lateral side 323 as shown in FIGS. 3A and 3B. In one implementation, this facilitates good thermal performance, for example, where the gap along the third lateral side 323 can include high power thermal hot spot circuitry and/or thermally sensitive circuitry which can benefit from the full die thickness 314 at that location. The lateral corners and the other lateral sides 324-326 have lower plastic work density due to the reduced die thickness of the indent 320 (e.g., to facilitate board level reliability benefits similar to those illustrated and described above in connection with FIG. 1C).

FIGS. 4 and 4A show a flip chip ball grid array (FCBGA) electronic device 400 having structures and features 401-407, 410-416, 418, 420-426, 428, and 429 that generally correspond to the respective structures and features 101-107, 110-116, 118, 120-126, 128, and 129 described above in connection with FIGS. 1-1B except as described differently hereinafter. The electronic device 400 has indent(s) 420 that can be of any suitable size and form, for example, as described above in connection with the indents 120, 220, 320 of FIGS. 1-3B. In one example, the semiconductor die 410 has a thickness 414 along the third direction Z of approximately 100 μm and the indent 420 has a depth 416 of approximately 50 μm and a width 418 of approximately 500 μm. The electronic device 400 also has a substrate 407 with a bottom side having conductive features. Some of the bottom side substrate features are soldered to the conductive terminals 411 of the semiconductor die 410 and an underfill material 408 extends between the first side 421 of the semiconductor die 410 and the substrate 407. Any suitable underfill material 408 can be used, such as an epoxy underfill composition for mechanical support, die passivation and adhesion to the substrate 407 and to help lower solder joint strain and protect against moisture. The electronic device 400 provides solder balls 409 arranged in an array with a lateral spacing distance of approximately 0.4 mm that are attached to further conductive features of the substrate 407. In the illustrated example, the solder balls 409 are attached to corresponding conductive features on the outer periphery of the bottom side of the substrate 407 for connection to conductive pads of a host circuit board (not shown). In this configuration, the second side 422 of the semiconductor die 410 and the included indent(s) 420 face the host circuit board. In another implementation, the substrate 407 can have top side conductive features that allow attachment of solder balls 409 to the top side thereof.

FIGS. 5-5B show examples of another flip chip ball grid array (FCBGA) electronic device 500 having structures and features 501-507, 510-516, 518, 520-526, 528, and 529 that generally correspond to the respective structures and features 101-107, 110-116, 118, 120-126, 128, and 129 described above in connection with FIGS. 1-1B except as described differently hereinafter. The electronic device 500 has one or more indent(s) 520 that can be of any suitable size and form, for example, as described above in connection with the indents 120, 220, 320, 420 of FIGS. 1-4A. In one example, the indent 520 has a depth 516 of approximately 400 μm and a width 418 of approximately 1 mm. The electronic device 500 also has a substrate 507 with a bottom side having conductive features. Some of the bottom side substrate features are soldered to the conductive terminals 511 of the semiconductor die 510 and an underfill material 508 extends between the first side 521 of the semiconductor die 510 and the substrate 507. Any suitable underfill material 508 can be used, such as an epoxy underfill composition for mechanical support, die passivation and adhesion to the substrate 507 and to help lower solder joint strain and protect against moisture. The electronic device 500 provides solder balls 509 arranged in an array and attached to further conductive features of the substrate 507 along the substrate top side. In the illustrated example, the solder balls 509 are attached to corresponding conductive features on the outer periphery of the top side of the substrate 507 for connection to conductive pads of a host circuit board (not shown) with the second side 522 of the semiconductor die 510 and the included indent(s) 520 facing away from the host circuit board. In another configuration, the second side 522 of the semiconductor die 510 and the included indent(s) 520 can face the host circuit board and the solder balls 509 can be attached to corresponding conductive features on the bottom side of the substrate 507. In the illustrated implementation, the substrate 507 has top side conductive features that allow attachment of solder balls 509 to the top side thereof. In another example, a molded package structure (not shown) can be formed to enclose the semiconductor die 510, and the package structure may expose the top side of a metal lid 530.

The examples of FIGS. 5-5B also include a metal lid 530 that is attached to the second side 522 of the semiconductor die 510 and a thermal interface material (TIM) 532 that extends between the second side 522 of the semiconductor die 510 and the metal lid 530. The sectional side view of FIG. 5 shows one example implementation, in which the thermal interface material 532 extends into the indent 520 between the semiconductor die 510 and the metal lid 530. FIG. 5A shows a sectional side view of another example implementation, in which the thermal interface material 532 does not extend into the indent 520 between the semiconductor die 510 and the metal lid 530. The absence of the thermal interface material 532 in the indent 520 in the example of FIG. 5A can help reduce the interfacial stress between the substrate 507 and the semiconductor die 520 and lower the risk of ILD cracking near the indent 520.

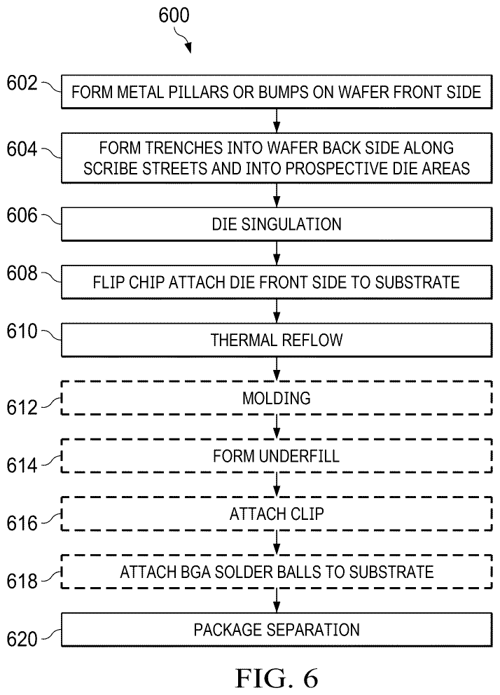

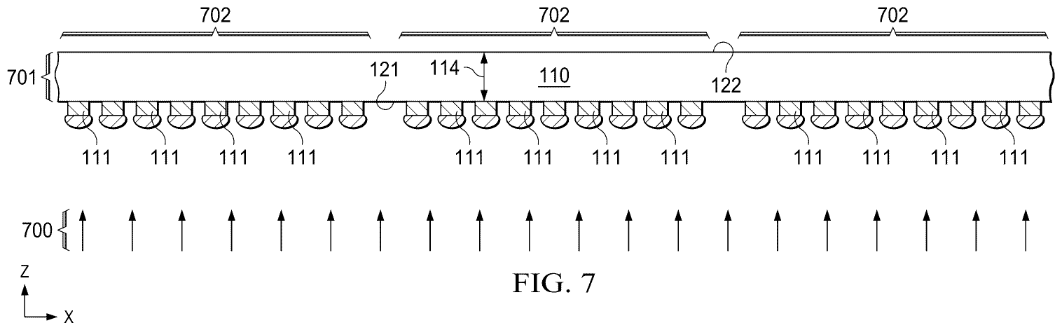

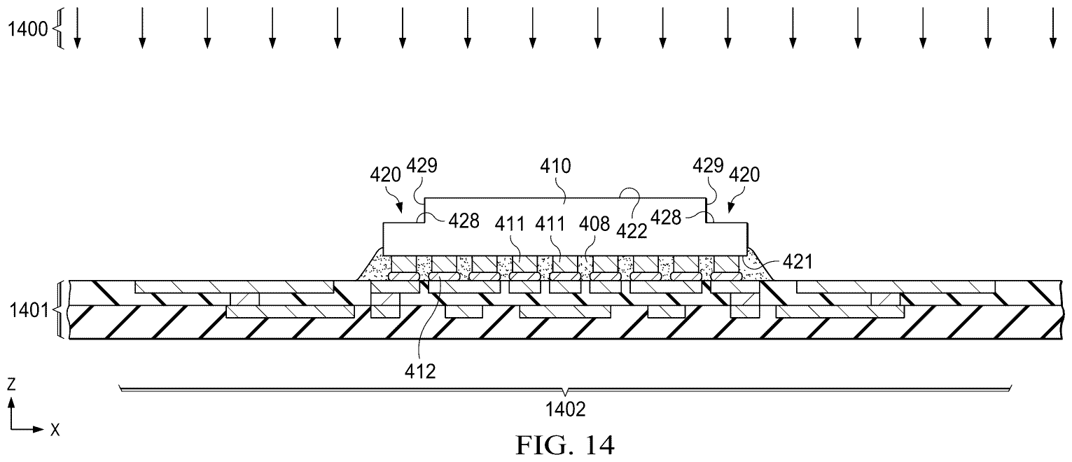

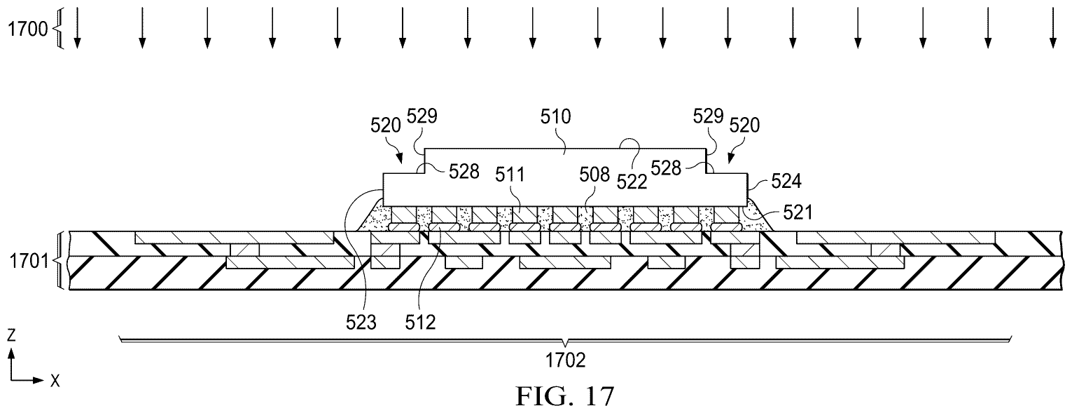

FIG. 6 shows a method 600 of fabricating an electronic device, FIGS. 7-13 show the example FCQFN electronic device 100 of FIGS. 1-1B undergoing fabrication processing according to an implementation of the method 600, FIGS. 14-16 show an example of the FCBGA electronic device 400 of FIGS. 4 and 4A undergoing fabrication processing according to another implementation of the method 600, and FIGS. 17-20 show an example of the FCBGA electronic device 500 of FIGS. 5-5B undergoing fabrication processing according to another implementation of the method 600. The method 600 begins at 602 in FIG. 6 with bumping to form conductive terminals 111 (e.g., metal pillars or bumps) along the front side of a wafer. FIG. 7 shows one example, in which a bumping process 700 is performed on the first (e.g., front) side 121 of a processed wafer 701 that also has an opposite second side 122 (the back side) before individual dies are singulated or separated from the starting wafer structure 701. The process 700 forms the conductive terminals 111 in each of a number of prospective die areas 702 that extend outward along the third direction Z from the first side 121 of the wafer 701.

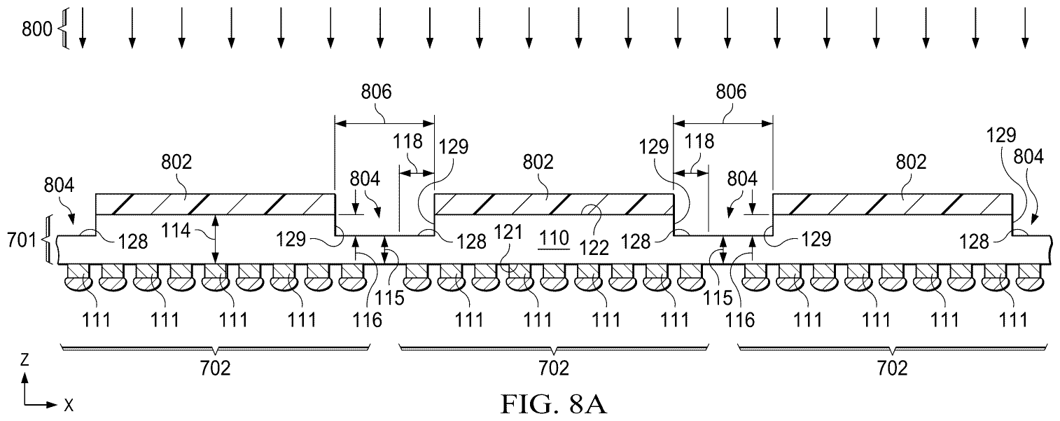

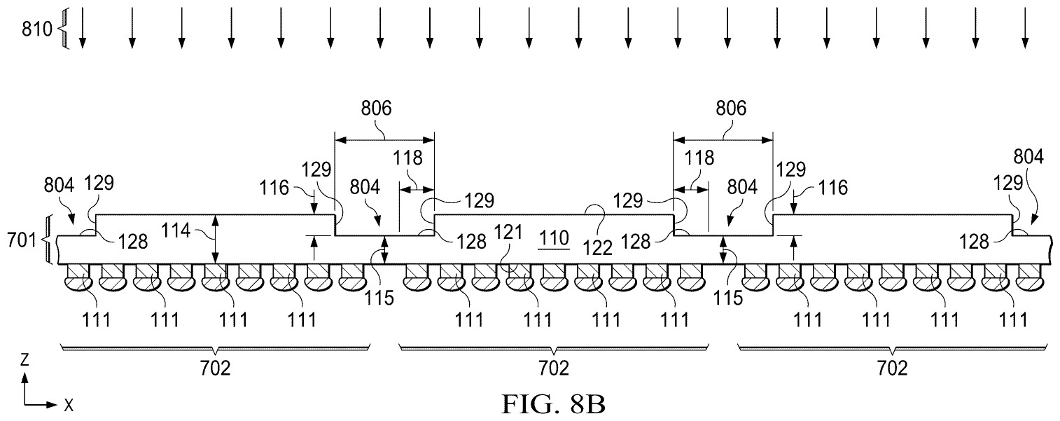

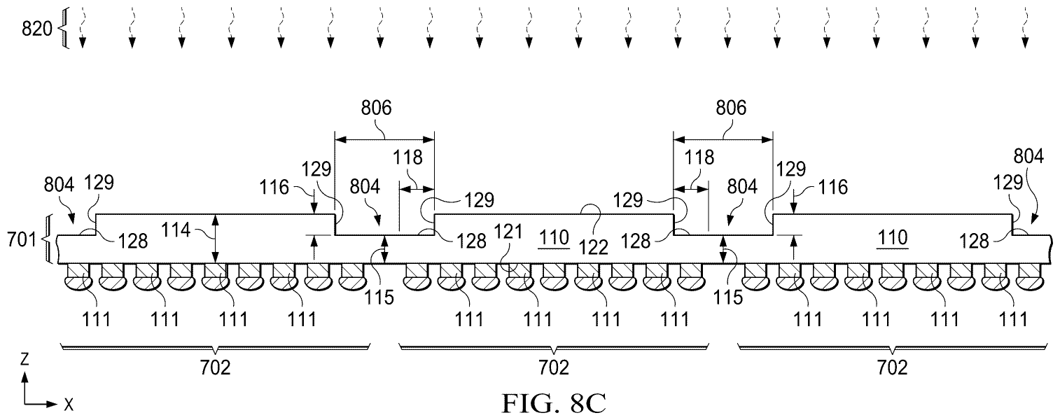

The method 600 continues at 604 in FIG. 6 with trench formation at 604. The processing at 604 forms one or more trenches in the wafer backside to form all or portions of the indents 120, 220, 320, 420, 520 illustrated and described above. FIGS. 8A-8C show three example implementations of the trench formation at 604 in FIG. 6. In the example of FIG. 8A, the trench formation includes performing an etch process 800 using a patterned etch mask 802 to form trenches 804 along scribe streets into the back or second side 122 of the wafer 701. The etch process 800 in one example forms the trenches 804 to a depth along the third direction Z to correspond to the prospective indent depth 116 described above. The trench formation in one example is done at the wafer level prior to die separation and may be part of a multi-step dicing or die singulation process, although wafer level trench formation is not a requirement of all possible implementations. The trenches 804 in one example have a lateral width 806 that is longer than twice the prospective indent width 118 described above. In the illustrated example, the trenches 804 straddle adjacent prospective die areas 702. Subsequent die singulation along the scribe streets leaves the above described indents 120, 220, 320, 420, 520 that extend downward into the second sides 122, 222, 322, 422, 522 and at least partially along a separated lateral side of the semiconductor dies 110, 210, 310, 410, 510. In one example, the etch process 800 is a reactive ion etch (RIE) process. In another example, the etch process 800 is an electron cyclotron resonance (ECR) etch process. In another example, the etch process 800 is an inductively coupled plasma (ICP) etch process. In another example, the etch process 800 is a capacitively coupled plasma (CCP) etch process.

FIG. 8B shows an alternate implementation using laser ablation for trench formation at 604 of FIG. 6. In this example, a laser ablation process 810 is performed in FIG. 8B using a laser (not shown) to form the trenches 804 that extend into the side 122 of the semiconductor wafer 701. The laser ablation process 810 in one implementation can form the trenches 804 as part of a multi-step laser dicing process, for example, which includes high power laser ablation to remove material from the wafer backside 122 and form the trenches 804 as shown in FIG. 8B, followed by lower energy stealth dicing as part of a multistep die separation process.

FIG. 8C shows yet another alternate trench formation approach using grinding or cutting to form the trenches 804 at 604 of FIG. 6. A grinding or cutting process 820 is performed in FIG. 8C that forms the trenches 804 that extend into the side 122 of the semiconductor wafer 701. In one example, the process 820 uses a cutting or dicing blade or a grinding tool (not shown) that grinds the die material to form the trenches 804 along the scribe streets straddling adjacent prospective die areas 702 to a depth along the third direction Z to correspond to the prospective indent depth 116 described above and to the width 806 that is wider than twice the prospective indent width 118. The trench formation in one example is done at the wafer level prior to die separation. The trench cutting process 820 may be part of a multi-step dicing or die singulation process, for example, followed by subsequent laser dicing or cutting using a different (e.g., thinner) cutting blade, alone or in combination with expansion of a dicing tape to which the wafer 701 is attached for final die separation, although not a requirement of all possible implementations.

Other material removal processes and tools can be used to form the trenches 804 in the backside of the wafer 701 at 604 in FIG. 6 prior to final die separation at 606. The trench formation may be incorporated into a die singulation process flow, for example, to initially form the trenches 804 using any suitable technique (e.g., etching, grinding, laser ablation, saw cutting, etc., or combinations thereof) followed by die separation processing using the same or a different form of die separation. In other implementations, the indents can be formed following die singulation using any suitable techniques (e.g., etching, grinding, laser ablation, saw cutting, etc., or combinations thereof).

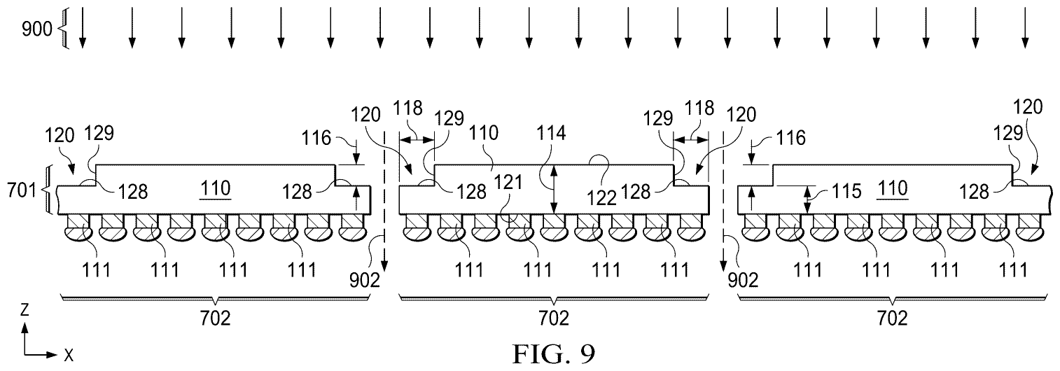

The method 600 continues at 606 in FIG. 6 in the illustrated example with die singulation. FIG. 9 shows one example, in which a die singulation or separation process 900 is performed that separates the individual semiconductor dies 110 from one another and from the starting wafer structure. Any suitable die singulation process 900 and tooling can be used, for example, etching, grinding, laser ablation, saw cutting, etc., or combinations thereof. The die singulation process 900 separates adjacent semiconductor dies 110 from one another along lines 902 and creates the lateral sides 123-126 of the individual semiconductor dies 110. The singulation process 900, moreover, is performed along the scribe streets of the starting wafer structure and leaves the indents 120 having the shapes and dimensions as described above (e.g., in connection with FIGS. 1-1B).

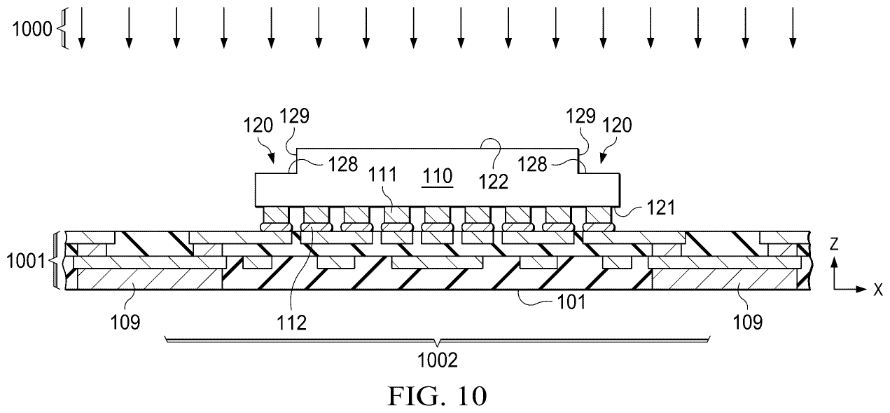

The method 600 continues at 608 in FIG. 6 with attaching the conductive terminals 111, 112 along the first side 121 of the semiconductor die 110 to respective conductive features of a substrate 107. FIG. 10 shows one example, in which a die attach process 1000 is performed using a starting substrate panel array 1001 with multiple unit areas 1002, one of which is illustrated. In one implementation, solder paste is formed (e.g., by printing, silk screening, dispensing, or other suitable technique) in select portions on certain conductive features of a top side of the substrate 1001. In another example, solder tips 112 are formed on the distal ends of the conductive terminals 111 of the semiconductor die 110, such as by dipping, or solder 112 can be provided at the ends of the conductive terminals 111 during wafer processing. The semiconductor dies 110 are positioned with the conductive terminals 111 on respective conductive features in each unit area 1002 of the substrate 1001, for example, using automated pick and place equipment (not shown). The illustrated example is a flip-chip die attach process 1000, which can be used alone or in combination with other component attachment techniques and equipment.

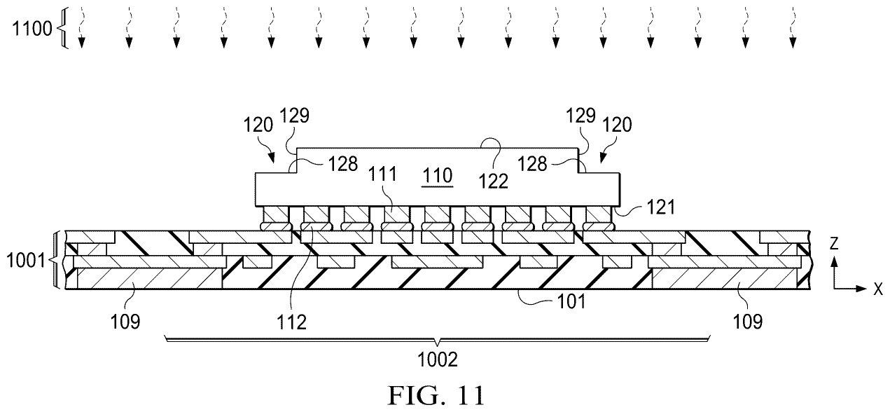

The method 600 continues at 610 in FIG. 6 with solder reflow processing. FIG. 11 shows one example, in which a thermal process 1100 is performed that reflows the solder paste to form solder connections between the semiconductor die copper pillar terminals 111 and the corresponding conductive metal features on the top side of the substrate panel array 1001. The flip-chip die attach processing at 608 and 610 in FIG. 6 can also include similar processing for attaching surface mount components (e.g., passive resistors, capacitors, inductors, transformers, active components such as transistors, etc., not shown) with terminals positioned on solder paste previously applied to corresponding conductive metal features of the substrate panel array 1001, followed by thermal reflow at 610 to form corresponding solder connections of the attached components to the multilevel package substrate panel array 1001.

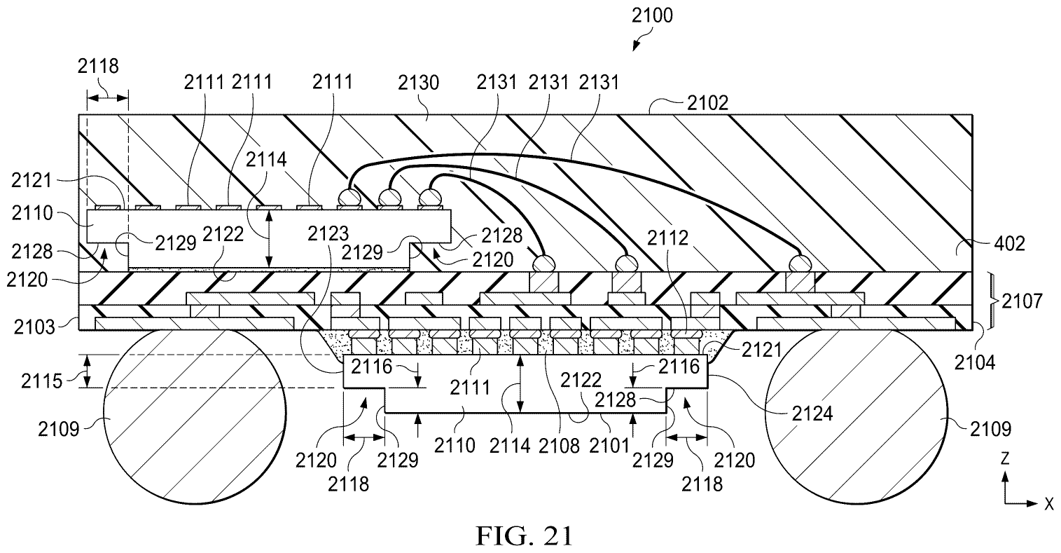

Another implementation can also include other die or component attachment processing, for example, after or instead of any included flip-chip solder reflow processing at 610. For example, one implementation can include forming die attach adhesive (not shown, e.g., by printing, silk screening, dispensing, etc.) on one or more conductive or non-conductive features of the substrate panel array 1001, followed by automated pick and place attachment of die back sides and/or other electronic components (not shown) on the die attach adhesive, followed by any beneficial adhesive curing process to form mechanical, structural attachment of the components to the substrate panel array 1001. In one implementation, the method 600 can include optional wire bonding, for example, to form bond wires (e.g., FIG. 21 below) that make any desired electrical connections between electronic components and/or conductive features in each unit area 1002 of the substrate panel array 1001. In other examples, such as strict flip-chip and surface mount technology (SMT) implementations, the wirebonding can be omitted.

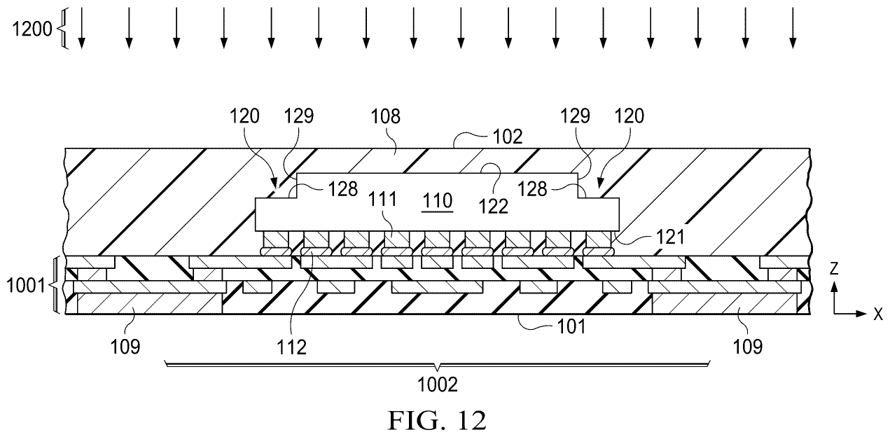

The method 600 continues at 612 in FIG. 6 in one example with optional molding or other suitable package structure formation to form the molded package structure 108 (e.g., FIGS. 1 and 1A above). FIG. 12 shows one example, in which a molding process 1200 is performed using a mold (not shown) that has a cavity with a top surface is generally planar and extends across the illustrated unit area 1002 and into scribe regions between adjacent unit areas 1002. In one implementation, a single mold cavity can be used to create a molded package structure 108 in each unit area 1002, which are subsequently separated during package separation processing (e.g., at 620 in FIG. 6). In other implementations, the individual mold cavities can be used for each unit area 1002 or groups of fewer than all unit areas 1002 can be included within a shared mold cavity (not shown). The molding process 1200 forms the molded package structure 108, which extends on the top side of the substrate 1001, on the sidewalls 123 and 124 and on the top 122 and the bottom 121 of the semiconductor die 110, and the molded package structure 108 extends into and fills the indents 120. In one example, the molding process 1200 forms mold compound 108 between the bottom side 121 of the individual semiconductor dies 110 and the top side of the substrate 1001 that extends between the conductive terminals 111 as shown in FIG. 12.

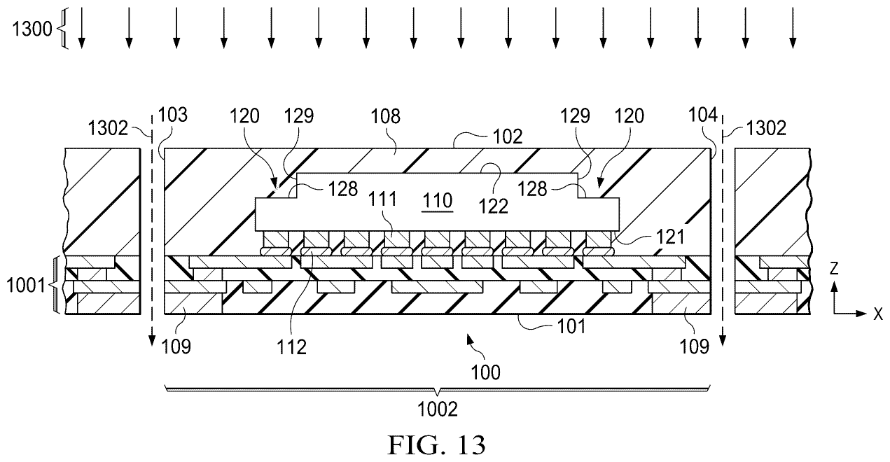

In one implementation, the method 600 proceeds with package separation at 620 in FIG. 6. FIG. 13 shows one example, in which a package separation process 1300 is performed that separates individual packaged electronic devices 100 from the starting substrate panel array structure 1001 along lines 1302 in scribe streets between adjacent rows and columns of unit areas of the starting array structure. In one implementation, the separation process 1300 includes saw cutting. In other implementations, one or more different separation processes can be used, for example, saw cutting, laser cutting, chemical etching, or combinations thereof, etc. This implementation of the method 600 provides the example electronic device 100 as described above in connection with FIGS. 1-1B.

Referring also to FIGS. 6 and 14-16, another implementation of the method 600 in FIG. 6 can be used to fabricate the FCBGA electronic device 400 of FIGS. 4 and 4A, with the molding at 612 omitted. In this example, the method 600 continues with underfill formation at 614 in FIG. 6 after flip chip die attach processing at 608 and 610 that attaches the above-described semiconductor die 410 to a multilevel package substrate panel array 1401 with unit areas 1402 (only one of which is illustrated). FIG. 14 shows one example, in which an underfill process 1400 is performed to form the underfill material 408 between the first side 421 of the semiconductor die 410 and the top side of the substrate panel array 1401. Any suitable underfill material 408 and process 1400 can be used at 614 in FIG. 6.

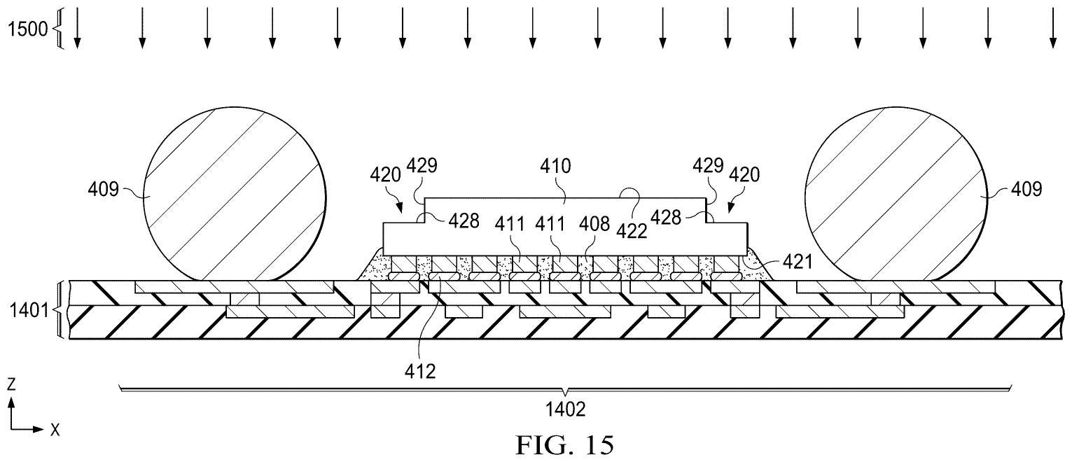

This implementation continues with BGA solder ball attachment at 618 in FIG. 6. FIG. 15 shows one example, in which a solder ball attachment process 1500 is performed (e.g., ball drop) to form and attach the solder balls 409 to further conductive features of the substrate panel array 1401. In the illustrated example, the solder balls 409 are attached to corresponding conductive features on the outer periphery of the bottom side of the substrate panel array 1401.

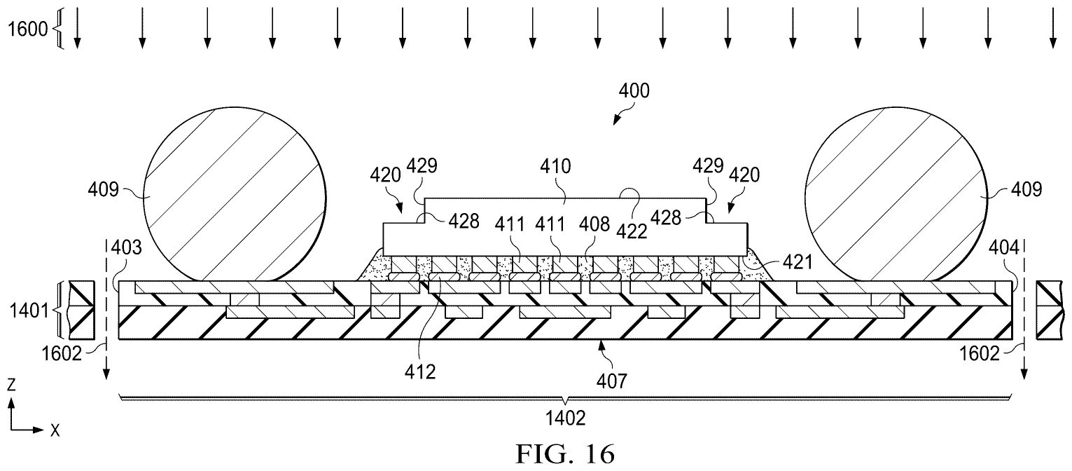

In this example, the method 600 of FIG. 6 proceeds (after solder ball formation at 618) to package separation at 620 as described above in connection with FIG. 13, for example, to provide individual packaged electronic devices 400 as described above in connection with FIGS. 4 and 4A. FIG. 16 shows one example, in which a package separation process 1600 is performed that separates individual packaged electronic devices 400 from the starting substrate panel array structure 1401 along lines 1602 in scribe streets between adjacent rows and columns of unit areas of the starting array structure. One example of the separation process 1600 includes saw cutting. In other implementations, different separation processes can be used, for example, saw cutting, laser cutting, chemical etching, or combinations thereof, etc., to provide the example FCBGA electronic device 400 as described above in connection with FIGS. 4 and 4A.

Referring also to FIGS. 6 and 17-20, a further example implementation of the method 600 in FIG. 6 can be used to fabricate the FCBGA electronic device implementations 500 in FIGS. 5-5B, with the molding at 612 omitted. In this example, the method 600 continues with underfill formation at 614 in FIG. 6 after flip chip die attach processing at 608 and 610 that attaches the above-described semiconductor die 510 to a multilevel package substrate panel array 1701 with unit areas 1702, one of which is illustrated in FIG. 17. In one example, an underfill process 1700 is performed in FIG. 17 to form the underfill material 508 between the first side 521 of the semiconductor die 510 and the top side of the substrate panel array 1701. Any suitable underfill material 508 and process 1700 can be used at 614 in FIG. 6.

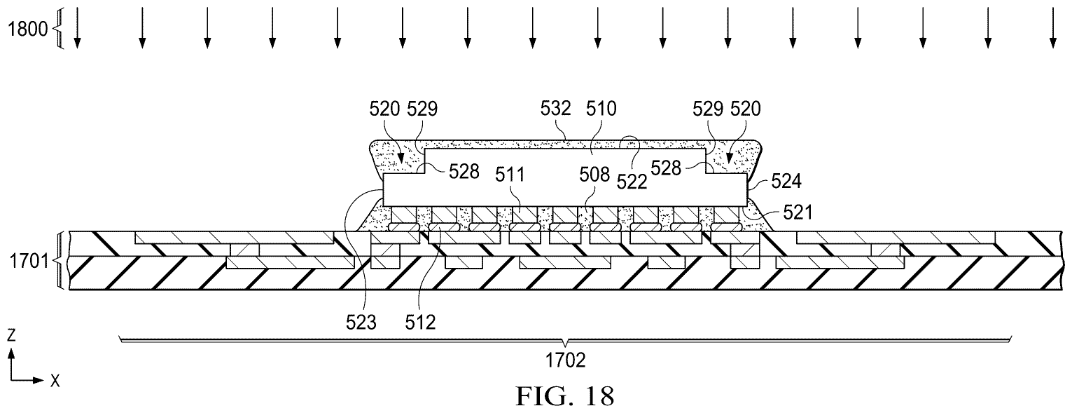

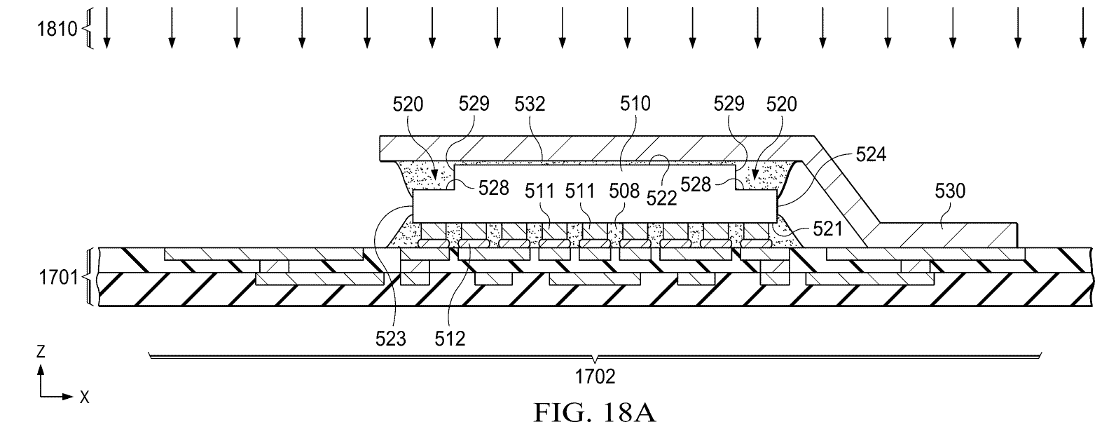

The method 600 in this example continues with clip or lid attachment at 616 in FIG. 6. FIGS. 18 and 18A show one example, in which a thermal interface material (TIM) 532 is formed by a suitable process 1800, such as dispensing, silk screening, printing, etc. In the illustrated example, the thermal interface material 532 is formed along the top side 522 of the semiconductor die 510, and the thermal interface material 532 extends into the indents 520 of the semiconductor die 510. This process 1800 can be used to form the example implementation of the electronic device 500 shown in FIG. 5 above. In another example, the thermal interface material formation process 1800 forms the material 532 along all or a portion of the top side 522 of the semiconductor die 510 without forming the thermal interface material 532 in the indents 520 of the semiconductor die 510. This can be used, for example, to form the example implementation of the electronic device 500 illustrated and described above in connection with FIG. 5A. Either implementation can also form thermal interface material along a portion of the top side of the substrate panel array 1701 for attachment of a second end of a metal lid (e.g., lid 530 in FIGS. 5-5B above).

FIG. 18A illustrates an example of lid placement at 616 in FIG. 6, in which an attachment process 1810 is performed that attaches an instance of the conductive metal lid 530 in each unit area 1702 of the substrate panel array 1701, for example, using automated pick and place equipment (not shown). The lid attachment at 616 (e.g., process 1810) can also include optional thermal interface material curing, for example, by application of heat, UV exposure, etc. (not shown).

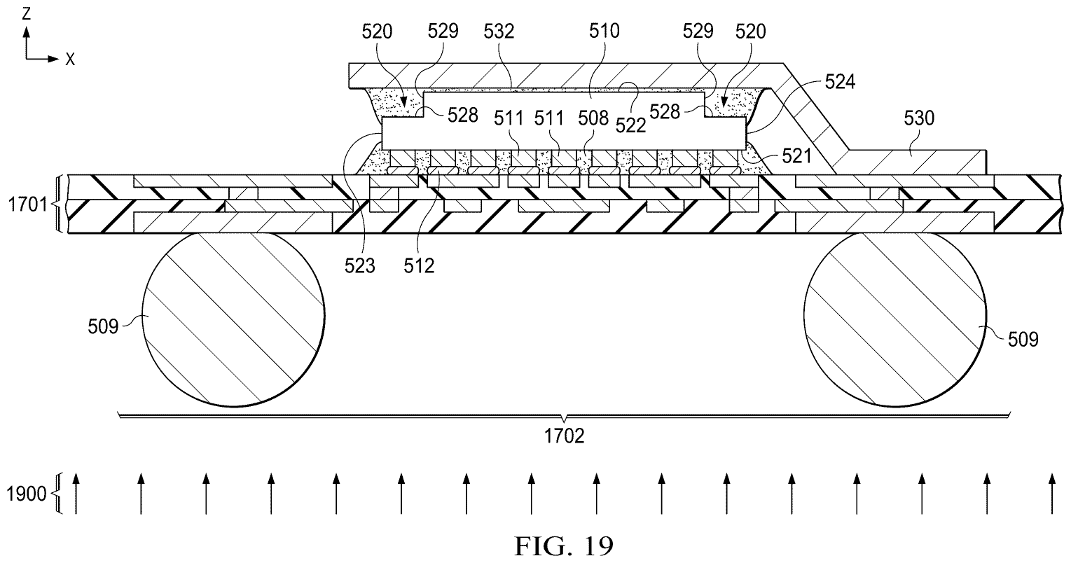

This implementation of the method 600 continues with BGA solder ball attachment at 618 in FIG. 6. FIG. 19 shows one example, in which a solder ball attachment process 1900 is performed (e.g., ball drop) to form and attach the solder balls 509 to further conductive features of the substrate panel array 1701. In the illustrated example, the solder balls 509 are attached to corresponding conductive features on the outer periphery of the bottom side of the substrate panel array 1701 laterally outward of the semiconductor die 510 in each unit area 1702.

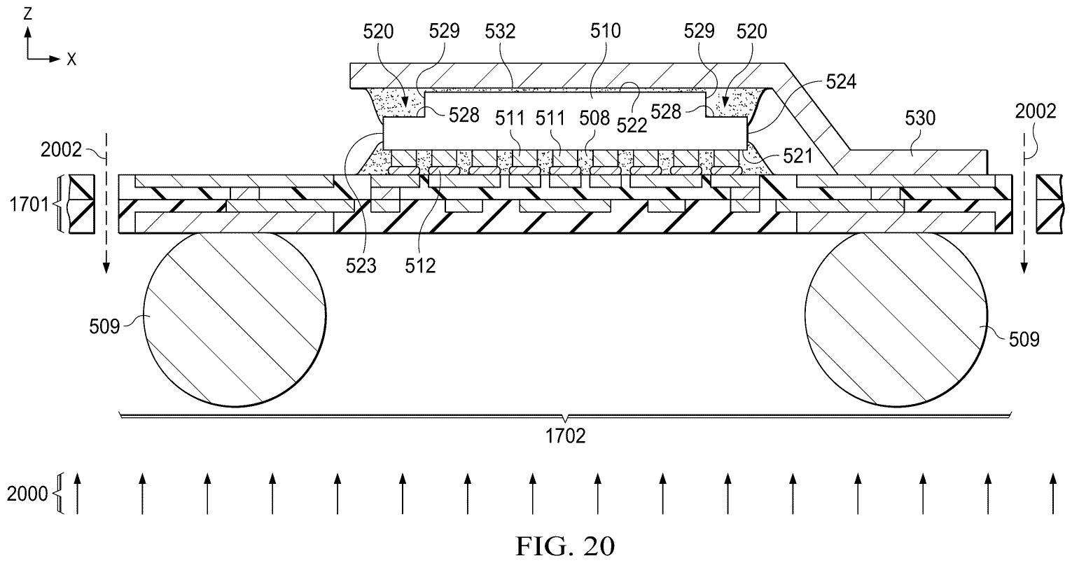

The method 600 in this example proceeds to package separation at 620 in FIG. 6 as described above in connection with FIG. 13, for example, to provide individual packaged electronic devices 500 as described above in connection with FIGS. 5-5B. FIG. 20 shows one example, in which a package separation process 2000 is performed that separates individual packaged electronic devices 500 from the starting substrate panel array structure 1701 along lines 2002 in the scribe streets between adjacent rows and columns of unit areas 1702 of the starting multilevel substrate panel array structure 1701. One example of the separation process 2000 includes saw cutting. In other implementations, different separation processes can be used, for example, saw cutting, laser cutting, chemical etching, or combinations thereof, etc., to provide the example FCBGA electronic device 500 as described above in connection with FIGS. 5-5B.

FIG. 21 is a sectional side elevation view of another FCBGA electronic device 2100 having a flip chip semiconductor die 2110 attached to the bottom side of a multilevel package substrate 2107 with a backside indent 2120. The example electronic device 2100 having structures and features 2101-2107, 2110-2116, 2118, 2120-2126, 2128, and 2129 that generally correspond to the respective structures and features 101-107, 110-116, 118, 120-126, 128, and 129 described above in connection with FIGS. 1-1B except as described differently hereinafter. In addition, the electronic device 2100 has solder balls 2109 and underfill material 2108 that generally corresponds to the solder balls 509 and underfill material 508 described above in connection with FIGS. 5-5B, as well as a molded package structure 2130 that generally corresponds to the molded package structure 108 described above in connection with FIGS. 1 and 1A. This example also includes a second instance of the semiconductor die 2110 that is attached to the top side of the substrate 2107 and includes a backside indent 2120. In addition, the electronic device 2100 of FIG. 21 includes bond wires 2131 that form respective electrical connections between the conductive metal terminals 2111 of the second instance of the semiconductor die 2110 and corresponding conductive metal features of the multilevel package substrate 2107.

Described examples advantageously provide a solution for enhanced board level reliability (BLR) without any or significant redesign of the semiconductor die, while providing a finished packaged electronic device structure with no change to the device footprint allowing easy integration into existing printed circuit board designs. The semiconductor die backside indented areas can be designed to facilitate board level reliability and can be tailored to accommodate thermal hotspots or thermally sensitive circuitry within a given semiconductor die without significant adverse effect on device thermal performance. Certain implementations can be easily integrated into existing semiconductor device manufacturing processes, for example, by incorporating the indent formation into existing die singulation or separation process flows, for example, to form the trenches 804 during wafer processing as part of an overall die separation process flow. The described solutions, moreover, can be advantageously applied to multiple package types with flip die and/or wire bonded designs (e.g., FCQFN, FCBGA, nfBGA, WCSP, etc.).

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a substrate having conductive features; and
a semiconductor die having opposite first and second sides, conductive terminals along the first side, and an indent that extends into the second side, the conductive terminals coupled to respective ones of the conductive features of the substrate.

2. The electronic device of claim 1, further comprising a package structure that extends in the indent and encloses the semiconductor die, wherein the substrate includes conductive leads.

3. The electronic device of claim 1, wherein the indent extends along at least a portion of a lateral side of the semiconductor die.

4. The electronic device of claim 1, wherein the indent extends along multiple lateral sides of the semiconductor die.

5. The electronic device of claim 1, further comprising an underfill material that extends between the first side of the semiconductor die and the substrate.

6. The electronic device of claim 1, further comprising a metal lid attached to the second side of the semiconductor die.

7. The electronic device of claim 6, further comprising a thermal interface material that extends between the second side of the semiconductor die and the metal lid.

8. The electronic device of claim 7, wherein the thermal interface material extends into the indent between the semiconductor die and the metal lid.

9. The electronic device of claim 7, wherein the thermal interface material does not extend into the indent.

10. The electronic device of claim 1, further comprising solder balls (409, 509) attached to further respective conductive features of the substrate.

11. The electronic device of claim 1, wherein the conductive terminals of the semiconductor die are soldered to respective ones of the conductive features of the substrate.

12. The electronic device of claim 1, wherein the conductive terminals of the semiconductor die are coupled to respective ones of the conductive features of the substrate by respective bond wires.

13. A system, comprising:
a circuit board having a conductive feature; and
an electronic device, including:
a substrate having first conductive features, and a second conductive feature that is soldered to the conductive feature of the circuit board; and
a semiconductor die having opposite first and second sides, conductive terminals along the first side, and an indent extending into the second side, the conductive terminals coupled to respective ones of the first conductive features of the substrate.

14. A method of fabricating an electronic device, the method comprising:
forming an indent into a second side of a semiconductor die; and
attaching conductive terminals along an opposite first side of the semiconductor die to respective conductive features of a substrate.

15. The method of claim 14, wherein forming the indent includes forming a trench into a side of a semiconductor wafer before separating the semiconductor die from the semiconductor wafer.

16. The method of claim 15, wherein forming the trench includes performing an etch process that etches the trench that extends into the side of the semiconductor wafer.

17. The method of claim 16, wherein the etch process is a reactive ion etch process.

18. The method of claim 16, wherein the etch process is an electron cyclotron resonance etch process.

19. The method of claim 16, wherein the etch process is an inductively coupled plasma etch process.

20. The method of claim 16, wherein the etch process is a capacitively coupled plasma etch process.

21. The method of claim 15, wherein forming the trench includes performing a laser ablation process that forms the trench that extends into the side of the semiconductor wafer.

22. The method of claim 15, wherein forming the trench includes performing a grinding or cutting process that forms the trench that extends into the side of the semiconductor wafer.
